(19) United States
(12) Patent Application Publication
(10) Pub. No.: US 2025/0116937 A1
(43) Pub. Date: Apr. 10, 2025

(54) LITHOGRAPHY PROCESS

(71) Applicant: TAIWAN SEMICONDUCTOR MANUFACTURING COMPANY, LTD., Hsinchu (TW)

(72) Inventors: Ming-Hui WENG, New Taipei City (TW); Wei-Han LAI, New Taipei City (TW); Hsien-Chung HUANG, Hsinchu City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/481,124

(22) Filed: Oct. 4, 2023

(51) Int. Cl. G03F 7/40; G03F 7/00; H01L 21/027; H01L 29/66

(52) U.S. Cl. CPC G03F 7/40; G03F 7/70616; H01L 21/0274; H10D 30/024; H10D 64/017

(57) ABSTRACT

A lithography method includes the steps which are mentioned below. A photoresist layer is formed over a substrate. The photoresist layer is exposed. The photoresist layer is developed. A vacuum treatment is performed to the photoresist layer. The substrate is etched by using the photoresist layer as an etch mask.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are a flowchart of an exemplary method for patterning a target layer, patterning a substrate, or patterning other layers in accordance with some embodiments.

FIGS. 2A, 3A, 4A, 4C and 5A are cross-sectional views of a semiconductor device at various stages of the method of FIGS. 1A and 1B in accordance with various aspects of the present disclosure.

FIGS. 2B, 3B, 4B and 5B are photoresist composition of the photoresist layer corresponding to FIGS. 2A, 3A, 4A and 5A, respectively.

FIGS. 6 and 7 are cross-sectional views of a semiconductor device at various stages of the method of FIGS. 1A and 1B in accordance with various aspects of the present disclosure.

FIGS. 8-11 are cross-sectional views of a semiconductor device at various stages of the method of FIGS. 1A and 1B in accordance with various aspects of the present disclosure.

FIG. 12A is a perspective view of the semiconductor device at various stages of the method of FIGS. 1A and 1B in accordance with various aspects of the present disclosure.

FIGS. 12B and 12C are cross-sectional views along line a1-a1 and line b1-b1 of FIG. 12A, respectively, in accordance with various aspects of the present disclosure.

FIGS. 13-16 are cross-sectional views of the semiconductor device at various stages of the method of FIGS. 1A and 1B in accordance with various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

Photoresists may include at least a polymer, photo acid generator, base (e.g., normal quencher or photo-decomposable quencher (PDQ)) and a solvent. To deposit photoresists over a substrate to form a film, the solvent evaporates and the other components form the film. At a post exposure bake (PEB) step, acid labile groups (ALG) of the polymer are cleaved by acid and the released ALG might remain in the photoresist between an exposed region and an unexposed region, forming a “semi-dissolved” region in the photoresists. At a developing step, additives from developer might penetrate and remain in the film. These remained components like ALG, PAG, base and the additives from the developer may act as plasticizer to reduce a glass temperature (T_{g}) of the photoresists and cause reflow of photoresists during an etch step or during a hard bake step, deteriorating local critical dimension uniformity (LCDU) performance after the etch step or hard bake step.

The present disclosure provides a lithography method including a vacuum treatment. Since the vacuum treatment is operated at a low pressure, unwanted remained components in the photoresists may evaporate or vaporize to prevent plasticizing effect. For example, a glass transition temperature (T_{g}) of the photoresists may be increased and reflow of the photoresists may be suppressed such that after an improved LCDU after an etch step or hard bake step can be obtained.

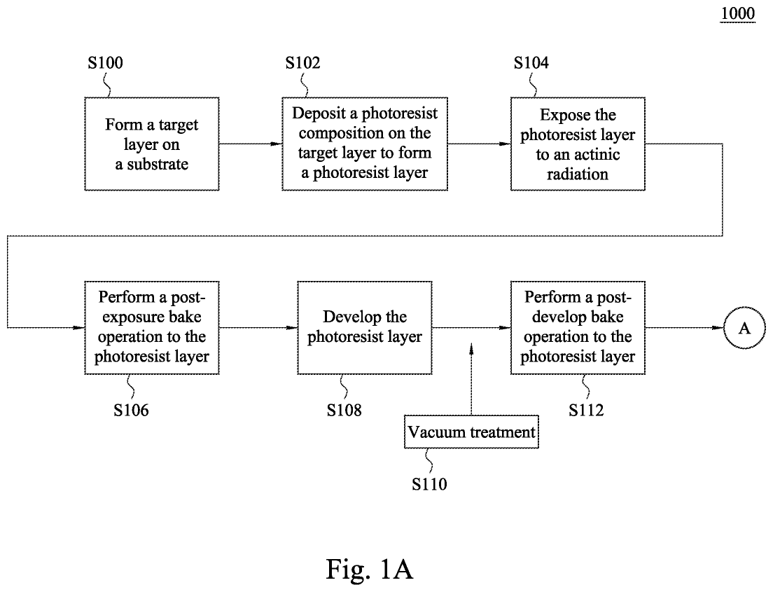

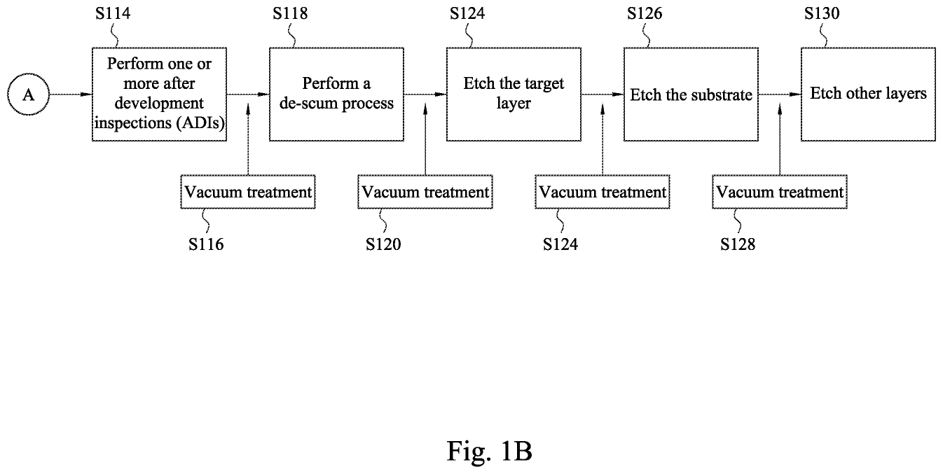

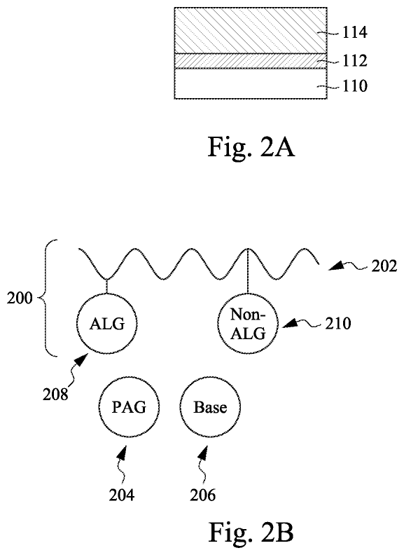

FIGS. 1A and 1B are a flowchart of an exemplary method 1000 for patterning a target layer, patterning a substrate, or patterning other layers in accordance with some embodiments. FIGS. 2A, 3A, 4A, 5A, 6 and 7 are cross-sectional views of a semiconductor device at various stages of the method 1000 of FIGS. 1A and 1B in accordance with various aspects of the present disclosure. FIGS. 2B, 3B, 4B and 5B are photoresist composition of the photoresist layer corresponding to FIGS. 2A, 3A, 4A and 5A, respectively.

The method 1000 includes a relevant part of an entire manufacturing process. It is understood that additional operations may be provided before, during and after the operations shown by FIGS. 1A and 1B, and some of the operations described below can be replaced or eliminated for additional embodiments of the method. The order of the operations/processes may be interchangeable. The method includes fabrication of a semiconductor device. However, the fabrication of the semiconductor device is merely an example for describing the manufacturing process according to some embodiments of the present disclosure.

The method 1000 begins at operation S100 in which the operation S100 includes forming a target layer on a substrate. With reference to FIGS. 1A, 2A and 2B, in some embodiments of operation S100, a target layer 112 to be patterned is formed on a substrate 110. A photoresist composition is deposited on the target layer 112 to form a photoresist layer 114. For example, the target layer 112 may be formed by an acceptable deposition process, such as chemical vapor deposition (CVD), physical vapor deposition (PVD), atomic layer deposition (ALD), spin coating process, or the like. The substrate 110 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

In some embodiments, the substrate 110 is a silicon substrate doped with a p-type dopant such as boron (for example a p-type substrate). Alternatively, the substrate 110 could be another suitable semiconductor material. For example, the substrate 110 may be a silicon substrate that is doped with an n-type dopant such as phosphorous or arsenic (an n-type substrate). The substrate 110 could include other elementary semiconductors such as germanium and diamond. The substrate 110 could optionally include a compound semiconductor and/or an alloy semiconductor. Further, the substrate 110 could include an epitaxial layer (epi layer), may be strained for performance enhancement, and may include a silicon-on-insulator (SOI) structure.

In some embodiments, the target layer 112 is substantially conductive or semi-conductive. The electrical resistance may be less than about 103 ohm-meter. In some embodiments, the target layer 112 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the target layer may contain Ti, Al, Co, Ru, TiN, WN₂, or TaN.

In some other embodiments, the target layer 112 contains a dielectric material with a dielectric constant in a range from about 1 to about 40. In some other embodiments, the target layer 112 contains Si, metal oxide, or metal nitride, where the formula is MX_{b}, wherein M is a metal or Si, and X is N or O, and wherein “b” is in a range from about 0.4 to 2.5. For example, the target layer 112 may contain SiO₂, silicon nitride, aluminum oxide, hafnium oxide, or lanthanum oxide.

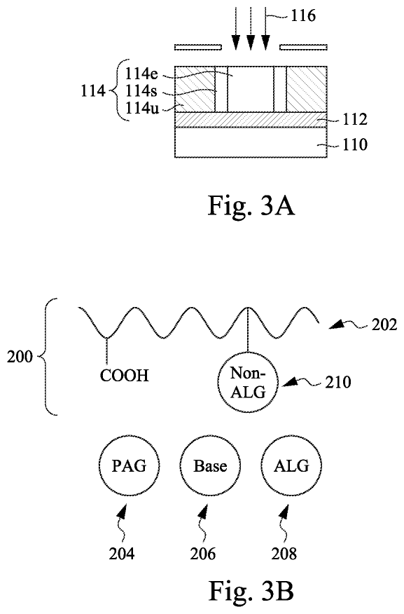

The method 1000 then proceeds to operation S102 in which the operation S102 includes depositing a photoresist composition on the target layer to form a photoresist layer. With reference to FIGS. 1A, 2A and 2B, in some embodiments of operation S102, a photoresist composition is deposited on the target layer 112 to form a photoresist layer 114. The photoresist composition deposited on the target layer 112 to form the photoresist layer 114 may be formed by spin coating process or deposition process. In some embodiments, the photoresist composition includes a polymer (e.g., an organic polymer) 200, a photo acid generator (PAG) 204, a base 206, and a solvent. The solvent evaporates and the other components form the photoresist layer 114, as shown in FIGS. 2A-2B. In some embodiments, the polymer 200 includes a polymer backbone 202, one or more acid cleavable acid labile groups (ALGs) 208 bonded to the polymer backbone 202, and one or more non-ALGs 210 bonded to the polymer backbone 202. The PAG 204 is configured to release an acid after an optical exposure (e.g., actinic radiation in FIG. 3A), and the acid will cleave the ALGs in a post exposure baking (PEB) operation such that the polymer become 202 more hydrophilic (see carboxyl group (—COOH) in FIG. 3B), which will be discussed in greater detail below.

The method 1000 proceeds to operation S104 in which the operation S104 includes exposing the photoresist layer to an actinic radiation. With reference to FIGS. 1A, 3A and 3B, in some embodiments of operation S104, the photoresist layer 114 is exposed to an actinic radiation 116. In some embodiments, the photoresist layer 114 is exposed to the actinic radiation 116 with an illumination wavelength which is substantially less than about 250 nm. For example, the actinic radiation 116 may include at least one of the KrF, ArF, extreme ultraviolet (EUV) radiation, E-beam or the like. As discussed previously, the PAG 204 releases acids after the actinic radiation 116.

The method 1000 proceeds to operation S106 in which the operation S106 includes performing a post-exposure bake operation to the photoresist layer. With reference to FIGS. 1A, 3A and 3B, in some embodiments of operation S106, a post-exposure bake operation is then performed to the photoresist layer 114. At the post exposure bake (PEB) operation, the ALG 208 of the polymer 200 is cleaved by the acid which is released by the PAG 204. After the acid cleaves the ALG 208 of the polymer 200, the polymer 200 becomes more hydrophilic. For example, during the PEB operation, the bounded ALG 208 releases the side chain group and reveal carboxyl group (—COOH) (see FIG. 3B). The released ALG 208 might remain in a semi-dissolved region 114s of the photoresist layer 114. For example, the photoresist layer 114 may include an exposed region 114e, an unexposed region 114u and a semi-dissolved region 114s in which the semi-dissolved region 114s is between the exposed region 114e and the unexposed region 114u.

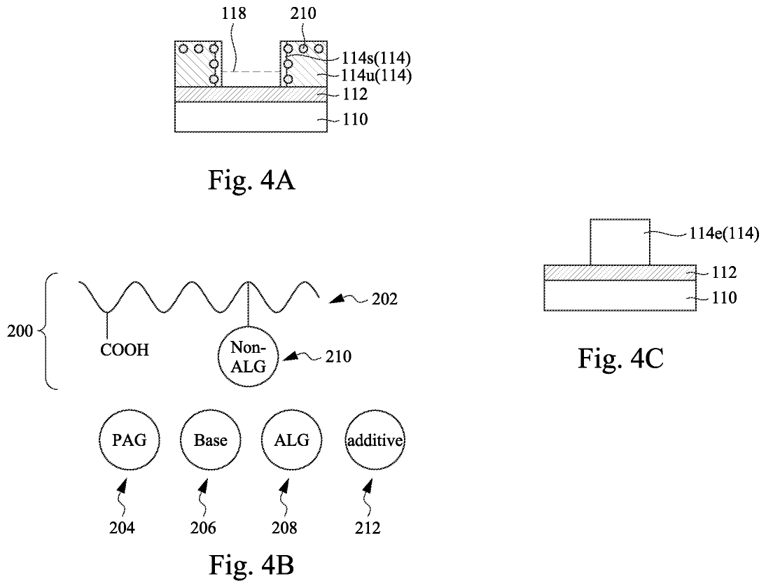

The method 1000 proceeds to operation S108 in which the operation S108 includes developing the photoresist layer. With reference to FIGS. 1A, 4A and 4B, in some embodiments of operation S108, the photoresist layer 114 is subsequently developed by applying a developer to the photoresist layer 114. At the developing step, additives 212 from the developer might penetrate and remain in the photoresist layer 114. For example, the additives 212 may remain in the semi-dissolved region 114s. In some embodiments, the developer can be a water-based solution or a solvent-based solution. For example, the water-based solution is a positive tone developer (PTD), such as a tetramethylammonium hydroxide (TMAH), and the exposed region 114e is removed by the PTD. The resulting structure is shown in FIG. 4A. In some other embodiments where the solvent-based solution is a negative tone developer (NTD), such as n-butyl acetate (nBA), the unexposed region 114u is removed by the NTD. The resulting structure is shown in FIG. 4C.

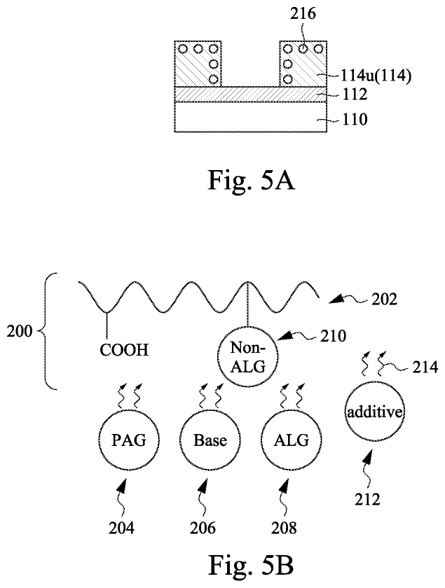

The method 1000 proceeds to operation S110 in which the operation S110 includes performing a vacuum treatment to the photoresist layer. With reference to FIGS. 1A, 5A and 5B, in some embodiments of operation S110, a vacuum treatment is performed to the photoresist layer 114 to evaporate or vaporize undesired remained components in the photoresist layer 114. For example, the remained PAG 204, base 206, ALG 208 and additive 212 from the developer are vaporized (shown as arrows 214), leaving tiny spaces 216. In some other embodiments, the tiny spaces 216 are absent after the vacuum treatment. In some embodiments, the vacuum treatment may be performed at a pressure under about 10 Torr and at a temperature higher than about 10° C. In some embodiments, the vacuum treatment may be referred to as a vacuum bake. The undesired remained components like ALG 208, PAG 204, base 206 and additive 212 may act as plasticizer to reduce a glass temperature of the photoresist layer 114. For example, prior to exposing the photoresist layer 114, the photoresist layer 114 has a first glass transition temperature. After developing the photoresist layer 114 and prior to performing the vacuum treatment, the photoresist layer 114 has a second glass transition temperature lower than the first glass transition temperature. For example, after performing a post-exposure bake operation to the photoresist layer 114 and prior to performing the vacuum treatment, the photoresist layer 114 has a third glass transition temperature, and the third glass transition temperature is lower than the first glass transition temperature. By removing the undesired remained components in the photoresist layer 114, the plasticizing effect can be prevented. The glass transition temperature of the photoresist layer 114 may be increased, and thus during a subsequent post-develop bake (PDB) operation or hard bake (e.g., operation S112 in FIG. 1A) or during a subsequent etch process which uses the photoresist layer 114 as an etch mask, the reflow of the photoresist layer 114 is suppressed. Therefore, improved LCDU performance can be obtained after the PDB or after the etch process. For example, after performing the vacuum treatment, the photoresist layer 114 has a fourth glass transition temperature higher than the second glass transition temperature and the third glass transition temperature.

In some embodiments, the vacuum treatment is performed to remove volatile fragments from the photoresist layer 114, wherein the volatile fragments are the photoresist composition or derivatives of the photoresist composition, and a weight of the photoresist layer 114 after performing the vacuum treatment is less than 99.9% of an initial weight of the photoresist layer 114 before performing the vacuum treatment. In some embodiments, the vacuum treatment is performed to extract the one or more volatile fragments with a weight percentage (wt %) greater than 0.1% of a total solid weight of the photoresist layer 114. For example, in some embodiments, the undesired remained components like ALG 208, PAG 204, base 206 and additive 212, which are the fragments from the lithography process extracted by the vacuum treatment, is in a range from about 0.05 weight percentage (wt %) to about 20 wt %, such as about 0.5 wt % to about 5 wt %, of a total solid weight of the photoresist layer 114.

In some embodiments, the vacuum treatment can remove the one or more volatile fragments from the photoresist layer 114 including formulae (A1) to (A6). In some embodiments, during the actinic radiation 116 (see FIGS. 3A and 3B), cations (such as triphenylsulfonium (TPS) or its derivatives) of the PAG 204 or the base 206 decompose into one or more small neutral fragments. For example, the cations of the PAG 204 or the base 206 may be TPS which has a formula (A1):

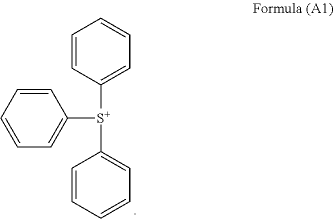 [SMILES: c1ccc([S+](c2ccccc2)c2ccccc2)cc1]

In some embodiments where the cations of the PAG 204 or the base 206 include the formula (A1), the one or more neutral fragments decomposed by the TPS may include compounds with various formulae. For example, the one or more small neutral fragments decomposed by the TPS may be compounds with the formulae (A2) and (A3):

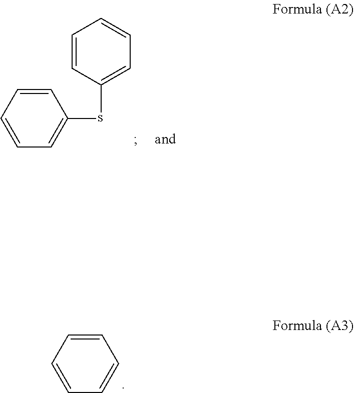

In some other embodiments, the one or more small neutral fragments decomposed by the TPS may be compounds with the formulae (A4), (A5) or (A6):

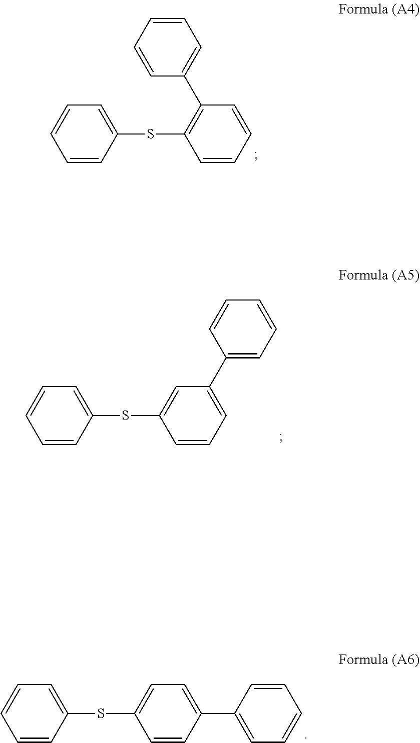 [SMILES: c1ccc(Sc2ccccc2-c2ccccc2)cc1 ; c1ccc(Sc2cccc(-c3ccccc3)c2)cc1 ; c1ccc(Sc2ccc(-c3ccccc3)cc2)cc1]

In the operation S110 in FIG. 1A, the vacuum treatment is performed prior to performing the PDB (i.e., operation S112 in FIG. 1A) In various embodiments, the vacuum treatment may be performed at different timing, which will be discussed in greater detail below. For example, the vacuum treatment is performed prior to performing a de-scum process (i.e., operation S118 in FIG. 1B), prior to etching the target layer (i.e., operation S122 in FIG. 1B) or prior to etching the substrate (i.e., operation S126 in FIG. 1B).

The method 1000 proceeds to operation S112 in which the operation S112 includes performing post-develop bake operation to the photoresist layer. With reference to FIGS. 1A, 4A and 4B, in some embodiments of operation S112, a post-develop bake operation is performed to the photoresist layer 114 to cure the photoresist layer 114.

The method 1000 proceeds to operation S114 in which the operation S114 includes performing one or more after development inspections (ADIs). With reference to FIGS. 1B, 4A and 4B, in some embodiments of the operation S114, one or more ADIs are performed to measure dimensions of the photoresist layer 114.

The method 1000 proceeds to operation S116 in which the operation S116 includes performing a vacuum treatment to the photoresist layer. With reference to FIGS. 1B, 5A and 5B, in some embodiments of the operation S116, a vacuum treatment is performed to the photoresist layer 114 to evaporate or vaporize the undesired remained components in the photoresist layer 114. For example, the undesired remained PAG 204, base 206, ALG 208 and additive 212 from the developer are vaporized (shown as arrows 214). The vacuum treatment in the operation S116 is similar to the vacuum treatment in the operation S110, and thus the description thereof is omitted herein.

The method 1000 proceeds to operation S118 in which the operation S118 includes performing a de-scum process to the photoresist layer. With reference to FIGS. 1B, 5A and 5B, in some embodiments of the operation S118, a de-scum process is performed to the photoresist layer to remove a bottom scum 118 (see. FIG. 4A) on the target layer 112. The bottom scum 118 may be formed due to a non-uniform exposure of the photoresist layer 114 during the operation S104, which includes exposing the photoresist layer to the actinic radiation. In some embodiments, the de-scum process may be performed by an etching process using suitable gases.

The method 1000 proceeds to operation S120 in which the operation S120 includes performing a vacuum treatment to the photoresist layer. With reference to FIGS. 1B, 5A and 5B, in some embodiments of operation S120, a vacuum treatment is performed to the photoresist layer 114 to evaporate or vaporize the undesired remained components in the photoresist layer 114. For example, the undesired remained PAG 204, base 206, ALG 208 and additive 212 from the developer are vaporized (shown as arrows 214). The vacuum treatment in the operation S120 is similar to the vacuum treatment in the operation S110 in FIG. 1A, and thus the description thereof is omitted herein.

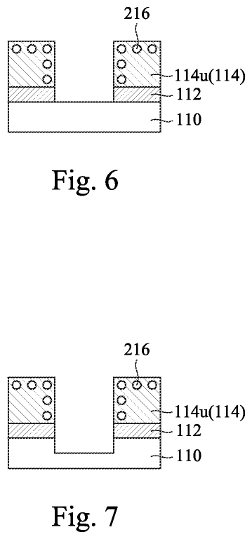

The method 1000 proceeds to operation S122 in which the operation S122 includes performing an etch process to the target layer. With reference to FIGS. 1B and 6, in some embodiments of operation S122, an etch process is performed to the target layer 112 using the photoresist layer 114 as an etch mask. For example, the etch process is a dry etch process including a biased plasma etch process that uses a chlorine-based chemistry, CF₄, NF₃, SF₆, or the like. The dry etch process may be performed anisotropically. In some embodiments, the plasma etch process may increase a stress in the photoresist layer 114 or input heat from the plasma into the photoresist layer 114. As discussed above, since the photoresist layer 114 has an increased glass transition temperature, the photoresist layer 114 may not reflow during the etch process. In other words, the reflow of the photoresist layer 114 is suppressed. Therefore, improved LCDU performance can be obtained after the etch process.

The method 1000 proceeds to operation S124 in which the operation S124 includes performing a vacuum treatment to the photoresist layer 114. With reference to FIGS. 1B and 6, in some embodiments of operation S124, a vacuum treatment is performed to the photoresist layer 114 to evaporate or vaporize the undesired remained components in the photoresist layer 114. For example, the undesired remained PAG 204, base 206, ALG 208 and additive 212 from the developer are vaporized. The vacuum treatment in the operation S124 is similar to the vacuum treatment in the operation S110 in FIG. 1A, and thus the description thereof is omitted herein. In some embodiments, during performing the etch process to the target layer 112, the plasma used in the etch process may decompose the photoresist layer 114, such as the unexposed region 114u of the photoresist layer 114 in FIG. 6 to release a plurality of species including a portion of the polymer backbone 202, polymer of the ALG 208, polymer of the non-ALG 210 in which each of these species has a molecular weight (MW) lower than an original molecular weight of the corresponding polymer backbone 202, the corresponding ALG 208, and the corresponding non-ALG 210. By using the vacuum treatment, a desired amount of the plurality of species including the portion of the polymer backbone 202, the polymer of the ALG 208, the polymer of the non-ALG 210 can be extracted. For example, the extracted plurality of species including the portion of the polymer backbone 202, the polymer of the ALG 208, the polymer of the non-ALG 210 is in a range from about 0.05 weight percentage (wt %) to about 20 wt %, such as about 0.5 wt % to about 5 wt %, of a total solid weight of the photoresist layer 114.

The method 1000 proceeds to operation S126 in which the operation S126 includes performing an etch process to the substrate. With reference to FIGS. 1B and 7, in some embodiments of operation S126, an etch process is performed to the substrate 110. For example, the etch process is a dry etch process including a biased plasma etch process that uses a chlorine-based chemistry, CF₄, NF₃, SF₆, or the like. The dry etch process may be performed anisotropically. In some embodiments, the plasma etch process may increase a stress in the photoresist layer 114 or input heat from the plasma into the photoresist layer 114. As discussed above, since the photoresist layer 114 has an increased glass transition temperature, the photoresist layer 114 may not reflow during the etch process. In other words, the reflow of the photoresist layer 114 is suppressed. Therefore, improved LCDU performance can be obtained after the etch process.

The method 1000 proceeds to operation S128 in which the operation S128 includes performing a vacuum treatment to the photoresist layer. With reference to FIGS. 1B and 6, in some embodiments of the operation S128, a vacuum treatment is performed to the photoresist layer 114 to evaporate or vaporize the undesired remained components in the photoresist layer. The vacuum treatment in the operation S128 is similar to the vacuum treatment in the operation S110 in FIG. 1A, and thus the description thereof is omitted herein.

The method 1000 proceeds to operation S130 in which the operation S130 includes performing an etch process to other layers. With reference to FIGS. 1B and 7, in some embodiments of the operation S130, an etch process is performed to other layers. In some embodiments, the etch process in the operation S130 is similar to the etch process S126 in the operation S122 or the etch process in the operation S126, and thus the description thereof is omitted herein. In the method 1000, a plurality of vacuum treatments are performed. For example, the vacuum treatment can be performed prior to performing the etch process or between each of the etch processes. In certain embodiments, one or more vacuum treatments selected from a group consisting of the operations S110, S116, S120, S124 and S128 are performed to the photoresist layer 114 to evaporate or vaporize the undesired remained components in the photoresist layer 114.

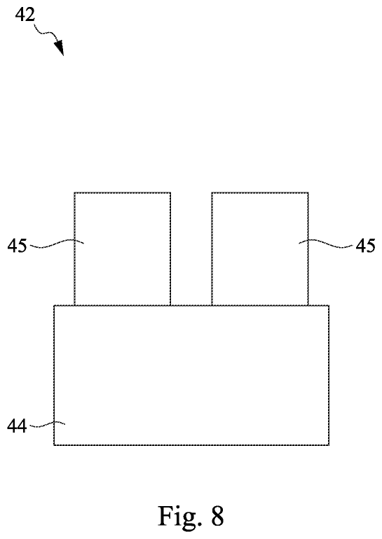

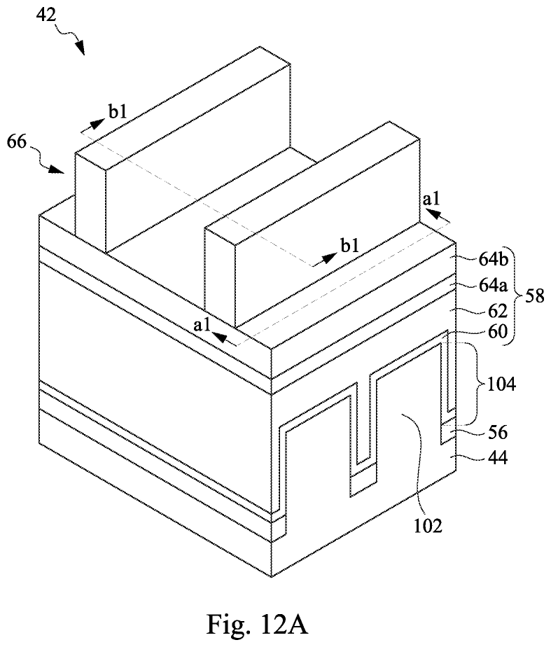

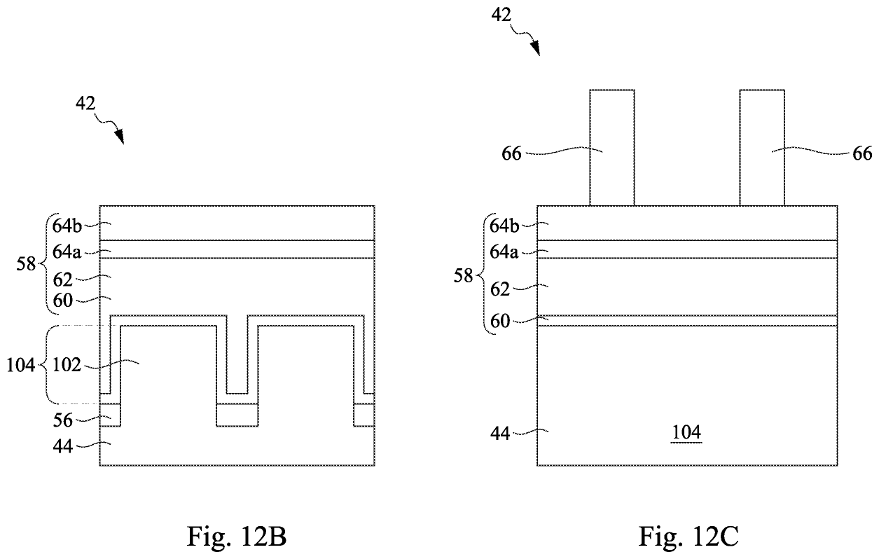

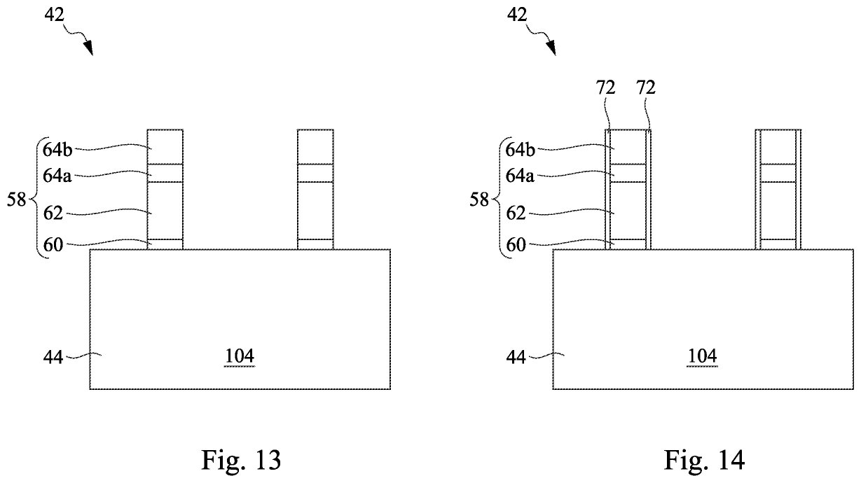

FIGS. 8-11 are cross-sectional views of a semiconductor device 42 at various stages of the method 1000 of FIGS. 1A and 1B in accordance with various aspects of the present disclosure. FIG. 12A is a perspective view of the semiconductor device 42 at various stages of the method 1000 of FIGS. 1A and 1B in accordance with various aspects of the present disclosure. FIGS. 12B and 12C are cross-sectional views along line a1-a1 and line b1-b1 of FIG. 12A, respectively, in accordance with various aspects of the present disclosure. FIGS. 13-16 are cross-sectional views of the semiconductor device 42 at various stages of the method 1000 of FIGS. 1A and 1B in accordance with various aspects of the present disclosure. Reference is made to FIG. 8. A photoresist layer 45 is formed on a substrate 44. The photoresist layer 45 and the substrate 44 are similar to the photoresist layer 114 and the substrate 110 in composition with regard to FIGS. 2A-2B, and thus the description thereof is omitted herein.

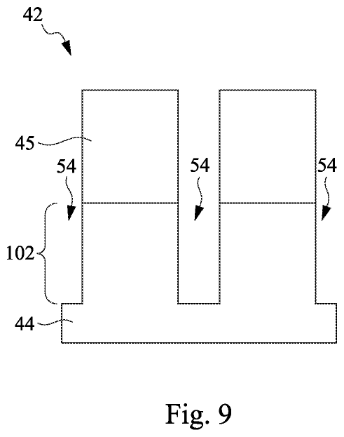

The photoresist layer 45 may be formed on the substrate 44 using multiple operations including the operations S102, S104, S106, and S108 in the method 1000 in FIG. 1A. Next, a vacuum treatment is performed to the photoresist layer 45 to evaporate or vaporize the undesired remained components in the photoresist layer 45. The vacuum treatment is similar to the vacuum treatment in the operation S110 in FIG. 1A, and thus the description thereof is omitted. In some embodiments, after performing this vacuum treatment, a post-develop bake operation is performed to the photoresist layer 45 to cure the photoresist layer. Afterwards, one or more operations including the operations S114, S116, S118, and S120 may be performed. Reference is made to FIG. 9. An etch process is performed to the substrate 44 using the photoresist layer 45 as an etch mask such that trenches 54 are formed in the substrate 44. In some embodiments, the etch process is similar to the operation S122, and thus the description thereof is omitted herein. Since the photoresist layer 45 has an increased glass transition temperature, the photoresist layer 45 may not reflow during the etch process. In other words, the reflow of the photoresist layer 45 is suppressed. Therefore, improved LCDU performance can be obtained after the etch process.

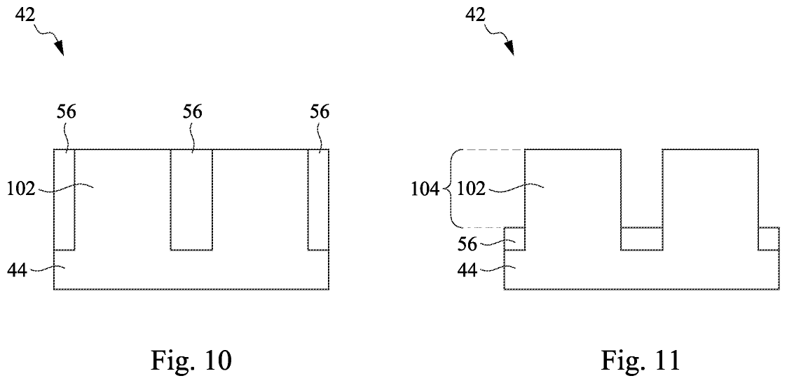

The photoresist layer 45 is removed after etching the substrate 44 by using a suitable photoresist stripper solvent or by a photoresist ashing operation. Isolation regions such as shallow trench isolation (STI) regions 56 may be formed on the substrate 44, filling into the trenches 54. The resulting structure in shown in FIG. 10.

The STI regions 56 may include a liner oxide (not shown). The liner oxide may be formed of a thermal oxide formed through a thermal oxidation of a surface layer of the substrate 44. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 56 may also include a dielectric material over the liner oxide, and the dielectric material may be formed using flowable chemical vapor deposition (FCVD), spin-on coating, or the like.

Referring to FIG. 11, the STI regions 56 are recessed, so that the top portions of semiconductor strips 102 protrude higher than top surfaces of the neighboring STI regions 56 to form protruding fins 104. The etching may be performed using a dry etching process or a wet etching process.

Referring to FIGS. 12A-12C, a dummy gate stack 58 is formed on top surfaces and sidewalls of the protruding fins 104. The dummy gate stack 58 may include a dummy gate dielectric 60 and a dummy gate electrode 62 over the dummy gate dielectric 60. The dummy gate dielectric 60 may be, for example, silicon oxide, silicon nitride, a combination thereof, or the like, and may be deposited or thermally grown according to acceptable techniques. The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material.

The dummy gate dielectric 60 may further include an interfacial layer (not shown) including silicon oxide. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56. The dummy gate stack 58 also has a lengthwise direction perpendicular to the lengthwise directions of protruding fins 104.

A photoresist layer 66 is formed over the dummy gate stack 58. In some embodiments, a pad layer (not shown) and a hard mask layer (not shown) may be formed between the photoresist layer 66 and the dummy gate stack 58. The pad layer and the hard mask layer have an etch selectivity with respect to the photoresist layer 66. The pad layer may be a silicon oxide layer and the hard mask layer may be a silicon nitride layer, for example. The above discussion of the photoresist layer 114 applies to the photoresist layer 66, unless mentioned otherwise. The above discussion of the vacuum treatment applies to the photoresist layer 66, unless mentioned otherwise. Since the photoresist layer 66 has an increased glass transition temperature, the photoresist layer 66 may not reflow during a subsequent etch process or a subsequent post-develop bake process. In other words, the reflow of the photoresist layer is suppressed. Therefore, improved LCDU performance can be obtained after the etch process.

In FIG. 13, using the photoresist layer 66 as a mask, the pattern of the photoresist layer 66 are extended into the dummy gate stack 58 by etching, using one or more suitable etchants. The photoresist layer 66 is at least partially removed during the etching operation in some embodiments. In other embodiments, the photoresist layer 66 is removed after etching the dummy gate stack 58 by using a suitable photoresist stripper solvent or by a photoresist ashing operation.

Next, as illustrated in FIG. 14, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

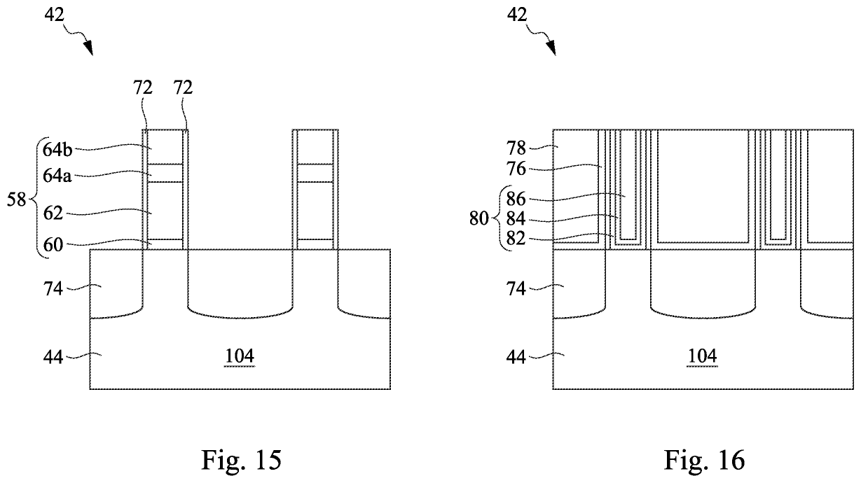

In FIG. 15, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, as such ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

Next, in FIG. 16, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 15) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, replacement gate structures 80 are respectively formed in the gate trenches. The gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 80 forms the gate associated with the three-sides of the channel region provided by the fin 104. Stated another way, each of the gate structures 80 wraps around the fin 104 on three sides. In various embodiments, the high-k/metal gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/metal gate structures 80 may include a metal, metal alloy, or metal silicide. Formation of the high-k/metal gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 84 may include work function metals to provide a suitable work function for the high-k/metal gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by including a vacuum treatment in a lithography method since the vacuum treatment is operated at a low pressure, undesired remained components in the photoresist layer may evaporate or vaporize to prevent plasticizing effect. Another advantage is that a glass transition temperature (T_{g}) of the photoresist layer may be increased and reflow of the photoresist layer may be suppressed such that after etch, improved LCDU can be obtained.

In some embodiments, a lithography method includes the following steps. A photoresist layer is formed over a substrate by depositing a photoresist composition over the substrate. The photoresist layer is exposed. The photoresist layer is developed. A vacuum treatment is performed to the photoresist layer to remove volatile fragments from the photoresist layer, wherein the volatile fragments are the photoresist composition or derivatives of the photoresist composition, and a weight of the photoresist layer after performing the vacuum treatment is less than 99.9% of an initial weight of the photoresist layer before performing the vacuum treatment. The substrate is etched by using the photoresist layer as an etch mask. In some embodiments, the vacuum treatment is performed after developing the photoresist layer. In some embodiments, the lithography method further comprises after developing the photoresist layer, performing a post-develop bake operation to the photoresist layer, wherein the vacuum treatment is performed after performing the post-develop bake operation. In some embodiments, the lithography method further comprises performing one or more after development inspections (ADIs) to measure a dimension of the photoresist layer, wherein the vacuum treatment is performed after performing the one or more ADIs. In some embodiments, the lithography method further comprises performing a de-scum process to the photoresist layer, wherein the vacuum treatment is performed after performing the de-scum process. In some embodiments, vacuum treatment is performed before etching the substrate.

In some embodiments, a lithography method includes the following steps. A target layer is formed over a substrate. A photoresist layer is formed over the target layer. The photoresist layer is exposed. The photoresist layer is developed. A first vacuum treatment is performed to the photoresist layer. The target layer is etched by using the photoresist layer as an etch mask. In some embodiments, the lithography method further comprises after etching the target layer, performing a second vacuum treatment to the photoresist layer. In some embodiments, the lithography method further comprises the following steps. After etching the target layer, a second vacuum treatment is performed to the photoresist layer. After performing the second vacuum treatment to the photoresist layer, the substrate is etched. In some embodiments, the lithography method further comprises the following steps. After developing the photoresist layer, a post-develop bake operation is performed to the photoresist layer. A second vacuum treatment is performed to the photoresist layer, wherein the second vacuum treatment is performed after performing the post-develop bake operation. In some embodiments, the lithography method further comprises the following steps. One or more after development inspections (ADIs) are performed to measure a dimension of the photoresist layer. A second vacuum treatment is performed to the photoresist layer, wherein the second vacuum treatment is performed after performing the one or more ADIs. In some embodiments, the lithography method further comprises the following steps. A de-scum process is performed to the photoresist layer. A second vacuum treatment is performed to the photoresist layer, wherein the second vacuum treatment is performed after performing the de-scum process. In some embodiments, prior to exposing the photoresist layer, the photoresist layer has a first glass transition temperature, and after developing the photoresist layer, the photoresist layer has a second glass transition temperature lower than the first glass transition temperature. In some embodiments, the lithography method further comprises performing a post-exposure bake operation to the photoresist layer after exposing the photoresist layer such that the photoresist layer has a third glass transition temperature, wherein the third glass transition temperature is lower than the first glass transition temperature. In some embodiments, after performing the first vacuum treatment to the photoresist layer, the photoresist layer has a fourth glass transition temperature higher than the second glass transition temperature.

In some embodiments, a lithography method comprises the following steps. A photoresist layer is coated over a substrate, wherein the photoresist layer comprises a polymer including a polymer backbone and one or more acid cleavable acid labile groups (ALGs) bonded to the polymer backbone, a solvent and a photo acid generator. The photoresist layer is exposed. A post-exposure bake operation is performed to the photoresist layer such that the ALGs are cleaved and remain in the photoresist layer. The photoresist layer is developed. A first vacuum treatment is performed to the photoresist layer to remove the ALGs. The substrate is etched using the photoresist layer as an etch mask. In some embodiments, the first vacuum treatment is performed after developing the photoresist layer. In some embodiments, the lithography method further comprises the following steps. After developing the photoresist layer, a post-develop bake operation is performed to the photoresist layer. A second vacuum treatment is performed to the photoresist layer, wherein the second vacuum treatment is performed after performing the post-develop bake operation. In some embodiments, the lithography method further comprises the following steps. One or more after development inspections (ADIs) are performed to measure a dimension of the photoresist layer. A second vacuum treatment is performed to the photoresist layer, wherein the second vacuum treatment is performed after performing the one or more ADIs. In some embodiments, the lithography method further comprises the following steps. A de-scum process is performed to the photoresist layer. A second vacuum treatment is performed to the photoresist layer, wherein the second vacuum treatment is performed after performing the de-scum process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography method, comprising:
forming a photoresist layer over a substrate by depositing a photoresist composition over the substrate;
exposing the photoresist layer;
developing the photoresist layer;
performing a vacuum treatment to the photoresist layer to remove volatile fragments from the photoresist layer, wherein the volatile fragments are the photoresist composition or derivatives of the photoresist composition, and a weight of the photoresist layer after performing the vacuum treatment is less than 99.9% of an initial weight of the photoresist layer before performing the vacuum treatment; and
etching the substrate by using the photoresist layer as an etch mask.

2. The lithography method of claim 1, wherein the vacuum treatment is performed after developing the photoresist layer.

3. The lithography method of claim 1, further comprising:
after developing the photoresist layer, performing a post-develop bake operation to the photoresist layer, wherein the vacuum treatment is performed after performing the post-develop bake operation.

4. The lithography method of claim 1, further comprising:
performing one or more after development inspections (ADIs) to measure a dimension of the photoresist layer, wherein the vacuum treatment is performed after performing the one or more ADIs.

5. The lithography method of claim 1, further comprising:
performing a de-scum process to the photoresist layer, wherein the vacuum treatment is performed after performing the de-scum process.

6. The lithography method of claim 1, wherein the vacuum treatment is performed before etching the substrate.

7. A lithography method, comprising:
forming a target layer over a substrate;
forming a photoresist layer over the target layer;
exposing the photoresist layer;
developing the photoresist layer;
performing a first vacuum treatment to the photoresist layer; and
etching the target layer by using the photoresist layer as an etch mask.

8. The lithography method of claim 7, further comprising:
after etching the target layer, performing a second vacuum treatment to the photoresist layer.

9. The lithography method of claim 7, further comprising:
after etching the target layer, performing a second vacuum treatment to the photoresist layer; and
after performing the second vacuum treatment to the photoresist layer, etching the substrate.

10. The lithography method of claim 7, further comprising:
after developing the photoresist layer, performing a post-develop bake operation to the photoresist layer; and
performing a second vacuum treatment to the photoresist layer, wherein the second vacuum treatment is performed after performing the post-develop bake operation.

11. The lithography method of claim 7, further comprising:
performing one or more after development inspections (ADIs) to measure a dimension of the photoresist layer; and
performing a second vacuum treatment to the photoresist layer, wherein the second vacuum treatment is performed after performing the one or more ADIs.

12. The lithography method of claim 7, further comprising:
performing a de-scum process to the photoresist layer; and
performing a second vacuum treatment to the photoresist layer, wherein the second vacuum treatment is performed after performing the de-scum process.

13. The lithography method of claim 7, wherein prior to exposing the photoresist layer, the photoresist layer has a first glass transition temperature, and after developing the photoresist layer, the photoresist layer has a second glass transition temperature lower than the first glass transition temperature.

14. The lithography method of claim 13, further comprising:
performing a post-exposure bake operation to the photoresist layer after exposing the photoresist layer such that the photoresist layer has a third glass transition temperature, wherein the third glass transition temperature is lower than the first glass transition temperature.

15. The lithography method of claim 13, wherein after performing the first vacuum treatment to the photoresist layer, the photoresist layer has a fourth glass transition temperature higher than the second glass transition temperature.

16. A lithography method, comprising:
coating a photoresist layer over a substrate, wherein the photoresist layer comprises:
a polymer including a polymer backbone and one or more acid cleavable acid labile groups (ALGs) bonded to the polymer backbone;
a solvent; and
a photo acid generator;
exposing the photoresist layer;
performing a post-exposure bake operation to the photoresist layer such that the ALGs are cleaved and remain in the photoresist layer;
developing the photoresist layer;
performing a first vacuum treatment to the photoresist layer to remove the ALGs; and
etching the substrate using the photoresist layer as an etch mask.

17. The lithography method of claim 16, wherein the first vacuum treatment is performed after developing the photoresist layer.

18. The lithography method of claim 16, further comprising:
after developing the photoresist layer, performing a post-develop bake operation to the photoresist layer; and
performing a second vacuum treatment to the photoresist layer, wherein the second vacuum treatment is performed after performing the post-develop bake operation.

19. The lithography method of claim 16, further comprising:
performing one or more after development inspections (ADIs) to measure a dimension of the photoresist layer; and
performing a second vacuum treatment to the photoresist layer, wherein the second vacuum treatment is performed after performing the one or more ADIs.

20. The lithography method of claim 16, further comprising:
performing a de-scum process to the photoresist layer; and
performing a second vacuum treatment to the photoresist layer, wherein the second vacuum treatment is performed after performing the de-scum process.
